(19) United States
(12) Patent Application Publication
(10) Pub. No.: US 2010/0090682 A1
(43) Pub. Date: Apr. 15, 2010

(54) Multi-Meter Test Lead Probe For Hands-Free Electrical Measurement of Control Panel Industrial Terminal Blocks

(76) Inventor: Eric A. Armstrong, Indianapolis, IN (US)

Correspondence Address: BOWMAN & ASSOCIATES, 1016 3rd Avenue, SW, Suite #106, CARMEL, IN, 46032, US

(21) Appl. No.: 12/639,039

(22) Filed: Dec. 16, 2009

Related U.S. Application Data
(63) Continuation-in-part of application No. 12/070,001, filed on Feb. 14, 2008.

(51) Int. Cl. G01R 1/06

(52) U.S. Cl. 324/114; 324/149

(57) ABSTRACT

An electrical test lead probe for use with a multi-meter provides for releasable retention in and electrical contact with a terminal of an industrial terminal block. The test lead probe includes a self-adjoining electrically conducting tip that is configured for automatic releasable receipt into a terminal block socket of various styles of terminal blocks, the terminal block socket housing a terminal of the terminal block. The present terminal block probe, in one form, is permanently attached to a multi-meter test lead. In another form, the present terminal block probe is coupled to a modular multi-meter test lead. In yet another form, the present terminal block probe has a removable head incorporating an electrically conducting, self-adjoining tip wherein the body is permanently attached to a multi-meter test lead. In a modular form, a plurality of terminal block probes may be provided each one of which has an electrically conducting tip of a different configuration corresponding to different configurations and/or sizes of terminal block sockets.

### RELATED APPLICATIONS

This U.S. patent application is a continuation-in-part of co-pending U.S. patent application Ser. No. 12/070,001 filed Feb. 14, 2008 entitled “Multi-meter Test Lead Probe for Hands-Free Voltage Measurement of Control Panel Industrial Terminal Blocks”, the benefit of and/or priority to being hereby claimed.

### BACKGROUND OF THE INVENTION

1. Field of the Invention

The present invention relates to equipment for taking electrical measurements of electrical circuits, components and/or devices and, more particularly, to multi-meter test lead probes for voltage measurement of control panel industrial terminal blocks.

2. Background Information

Industrial control systems use control panels to host electrical components that allow manufacturing processes to be automated. A common component among control panels is the industrial terminal block. Industrial terminal blocks have several uses within a control panel, but are used primarily to provide termination points between field devices and components within the industrial control panel. During system startup or troubleshooting, automation engineers and technicians use multi-meters such as digital multi-meters (DMMs) to take voltage readings at these industrial terminal blocks to help solve issues with the automated system.

Electrical test leads with measurement tools such as probes are used in conjunction with DMMs in order to manually connect the industrial terminal blocks of the industrial control panel with the DMM in order to obtain the electrical measurement. There are two types of industrial DMM test leads: modular and non-modular. Non-modular test leads have a connector on one end to insert into a DMM while the other end has a probe. Modular test leads have connectors at both ends that can be inserted into a DMM and/or a probe. Modular test leads allow an engineer or technician to carry one set of test leads and multiple probes each one of which having a specific function.

When taking electrical measurements of industrial control panel terminal blocks with present test leads (both modular and non-modular), the engineer or technician must use two hands: one to hold the neutral probe (typically black in color) and one to hold the positive voltage probe (typically red in color). Because of this, there are no free hands to hold and/or operate the DMM or to write or take notes. This can create an awkward situation. It would be advantageous if the user could have at least one free hand when taking a voltage measurement from an industrial terminal block of an industrial control panel.

It is therefore evident from the above that there is a need for a tool that will enable a user to use only one hand when taking electrical measurements of an industrial terminal block via a multi-meter and multi-meter test leads.

It is also therefore evident from the above that there is a need for a tool that will enable a user to easily take electrical measurements of various types of terminal blocks via a multi-meter and multi-meter test leads.

### SUMMARY OF THE INVENTION

The present invention is a multi-meter test lead probe having an electrically conductive tip that is configured to provide temporary automatic adjoining of the tip (i.e. a self-adjoining tip) to a terminal of a terminal block. This allows the multi-meter test lead probe to create temporary electrical contact with a terminal block terminal. The self-adjoining tip thus permits hands-free electrical measurement of various styles of terminal blocks.

The multi-meter probe is thus configured so as to provide releasable contact with a terminal of a terminal block, typically located within a socket or other opening of the terminal block. The tip is of an appropriate length to extend into the opening and allow the self-adjoining portion of the tip to adjoin with the terminal. The self-adjoining tip also allows for the multi-meter probe to be retained in and/or by the opening of the terminal block while maintaining electrical contact/connection with the terminal block terminal through a resilient connection element or member of the tip.

The self-adjoining electrically conducting tip is formed with a resilient member that provides an outward bias or spring against inward deformation. This allows the tip to reduce in a radial dimension while providing an outward radial bias (force). In one form, the tip is formed as a resilient element situated between two stationary elements. Other tip configurations are contemplated.

The present invention provides a test lead probe for use with a multi-meter for releasable retention in and electrical contact with a terminal of an industrial terminal block. The test lead probe includes a shortened body having an electrically conducting tip that is configured for releasable receipt into a terminal block socket of an industrial terminal block, the terminal block socket housing a terminal or terminal contact point of the terminal block.

In one form, the present terminal block probe is permanently attached to one end of a multi-meter test lead, the other end of which is preferably, but not necessarily, attached to or formed as a multi-meter test lead connector.

In another form, the present terminal block probe is configured to be coupled to a modular multi-meter test lead. In yet another form, the present terminal block probe has a removable head incorporating an electrically conducting and/or self-adjoining tip wherein the body is permanently attached to a multi-meter test lead.

In the modular form of the present terminal block probe, a plurality of terminal block probes may be provided each one of which has an electrically conducting tip of a different configuration corresponding to different configurations and/or sizes of industrial terminal block sockets. In the case of multiple terminal block probes connectable to the modular multi-meter test lead, a terminal block probe kit is defined. Since there are multiple manufacturers of industrial terminal blocks, and each manufacturer uses different sizes of terminal blocks with different types and/or sizes of sockets, the use of a modular form of the present invention allows the user to easily take electrical measurements of various terminal blocks. Moreover, in the modular form, if two terminal block probes of the present invention are used on both ends of the multi-meter test lead, the test lead may be used as a jumper between terminal blocks.

In the removable head form of the present terminal block probe, a plurality of heads are provided each one of which has an electrically conducting and self-adjoining tip of a different configuration corresponding to different industrial terminal blocks.

The present invention allows the user such as an engineer or technician to concentrate solely on the point of interest with the positive voltage probe. Moreover, if the engineer/technician would leave the control panel then return to take another voltage measurement, the neutral probe would be ready for use thus having only to grab the positive voltage probe.

The shortened configuration of the body of the present control panel terminal block probe provides less strain on a terminal block than present multi-meter probes.

The present invention will be more apparent upon reading the following detailed description in conjunction with the accompanying drawings.

### BRIEF DESCRIPTION OF THE DRAWINGS

The above mentioned and other features and objects of this invention, and the manner of attaining them, will become more apparent and the invention itself will be better understood by reference to the following description of embodiments of the invention taken in conjunction with the accompanying drawings, wherein:

FIG. 1 is a front view of an arrangement used to take voltage and/or other electrical measurements from one or more terminal blocks of an industrial control panel utilizing a digital multi-meter and an industrial terminal block probe fashioned in accordance with the present principles;

FIG. 2 is an enlarged side view of the industrial terminal block probe shown in FIG. 1;

FIG. 3 is a bottom view of the industrial terminal block probe of FIG. 2 taken along line 2-2 thereof;

FIG. 4 is a side view of multiple modular industrial terminal block probes for various types of industrial terminal blocks, each modular industrial terminal block probe utilizing a modular test lead, the multiple industrial terminal block probes constituting a kit;

FIG. 5 is a side view of an alternative embodiment of an industrial terminal block probe fashioned in accordance with the present principles and shown ready for reception in a contact of an industrial terminal block;

FIG. 6 is a side view of an embodiment of a modular terminal block probe fashioned in accordance with the present principles, the terminal block probe characterized by a self-adjoining electrically conducting tip;

FIG. 7 is an enlarged front view of the self-adjoining tip of the terminal block probe of FIG. 6 as taken along line 7-7 of FIG. 6;

FIG. 8 is a side view of the self-adjoining tip of FIG. 7 taken along line 8-8 thereof;

FIG. 9 is a side view of the self-adjoining tip of FIG. 7 taken along line 9-9 thereof; and

FIG. 10 is a side view of an embodiment of a non-modular terminal block probe fashioned in accordance with the present principles, the non-modular terminal block probe having the self-adjoining electrically conducting tip of the modular terminal block probe of

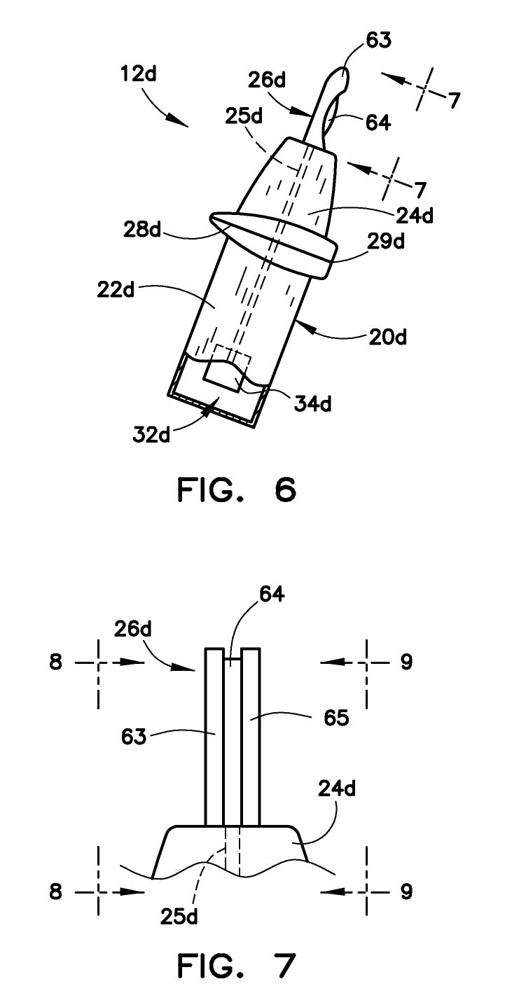

FIGS. 6-9, and shown ready for reception in probe locations in another style of a terminal block.

Like reference numerals indicate the same or similar parts throughout the several figures.

### DETAILED DESCRIPTION OF THE PREFERRED EMBODIMENT

Referring to FIG. 1, there is shown a digital multi-meter (DMM) generally designated 60 used to take voltage and other electrical measurements of various styles and/or types of terminal blocks such as the plurality of industrial terminal blocks 55 of an industrial control panel 50. A first electrical test lead 11 is shown plugged into a positive voltage receptacle of the DMM 60 and may be considered a positive test lead, while a second test lead 13 is shown plugged into a negative, neutral or ground voltage receptacle of the DMM 60 and may be considered a negative, neutral or ground test lead (hereinafter collectively, neutral test lead). Of course, the first and second test leads 11, 13, constituting a test lead pair, may be connected to the DMM 60 as is necessary for a particular electrical test. A conventional test lead probe 10 is attached to the positive test lead 11 and is adapted to be held by a user (e.g. an engineer or technician) and held in contact with a positive terminal or contact of one of the industrial terminal blocks 55 during a voltage measurement thereof. A terminal block probe and especially but not necessarily an industrial terminal block probe 12 (collectively hereinafter, an industrial terminal block probe) fashioned in accordance with the present principles is attached to the neutral test lead 13. The industrial terminal block probe 12 is configured to be received by or inserted into a socket of a terminal block and especially but not necessarily an industrial terminal block 55 (collectively hereinafter an industrial terminal block 55) of the control panel 50, be held within and/or by the socket of the industrial terminal block 55 and make contact with a terminal or contact of the socket of the industrial terminal block 55. The terminal or contact of the terminal block socket is especially, but not necessarily, a neutral, ground or negative terminal or contact. In this manner and as shown in FIG. 1, the present industrial terminal block probe 12 is retained hands-free by the industrial terminal block 55.

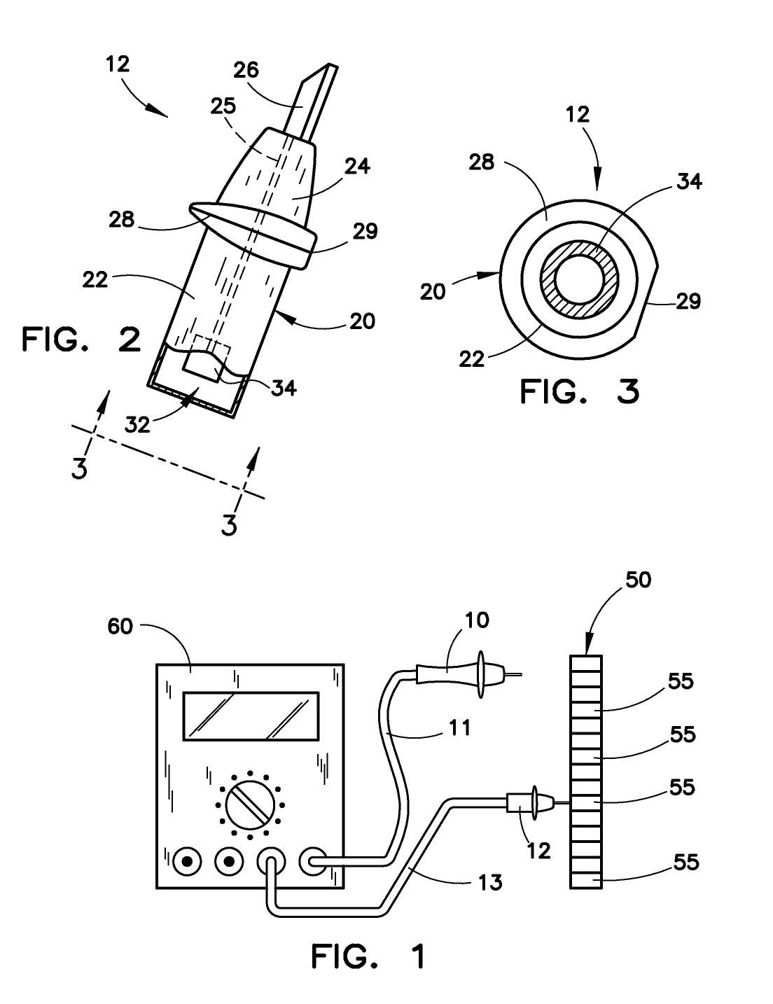

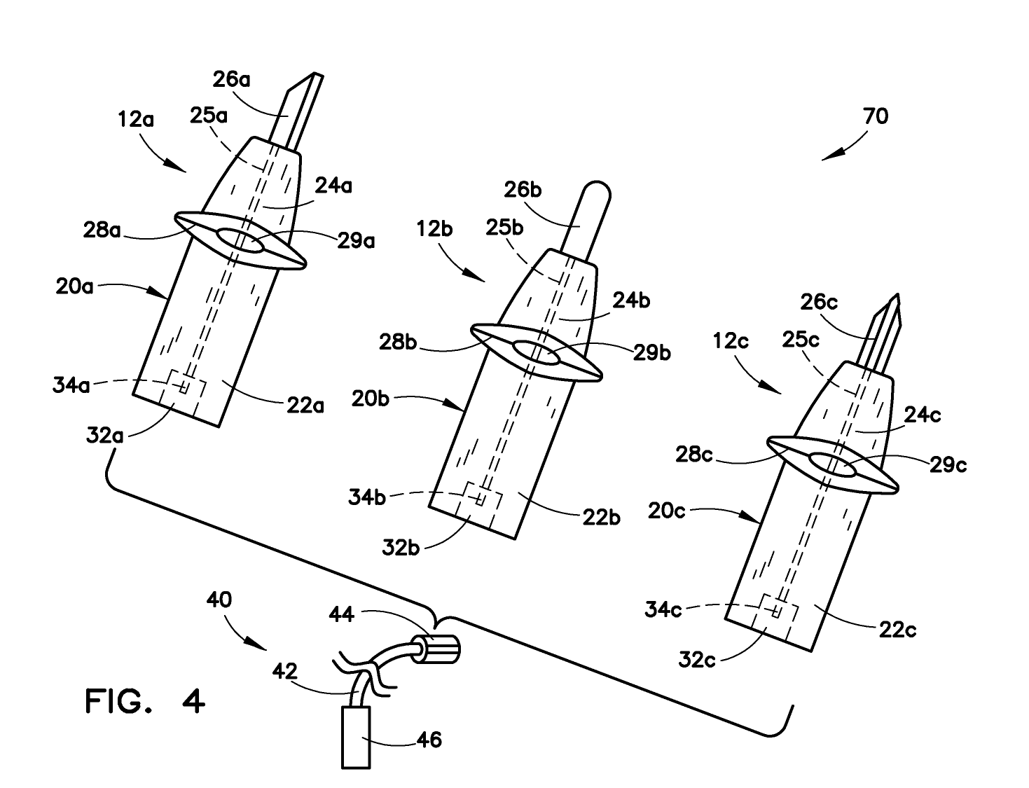

Referring additionally to FIGS. 2 and 3, the industrial terminal block probe 12 is shown in greater detail. Particularly, the terminal block probe 12 consists of a body 20 defined by a generally short cylindrical shaft 22 terminating at one end in a head 24 and including a circumferential finger grip 28. The body 20 may be formed of plastic but other materials may be used. The head 24 is generally frusto-conically shaped that axially extends from the grip 28 and terminates in an electrically conducting tip 26. The grip 28 is generally saucer shaped and includes a flat 29 on one side or edge thereof. The flat 29 provides a handling surface for the terminal block probe 12. The shaft 22 includes an opening or socket 32 in which is situated an electrical pad or terminal 34. The socket 32 and electrical terminal 34 are configured to receive a modular end of the test lead 13. In this regard, the terminal block probe 12 is a modular type probe. While not shown, the probe 12 may not be modular and therefore be permanently connected to the test lead 13. The terminal 34 is electrically connected to the electrically conducting tip 26 via a wire or the like 25 that extends through the body 20 from the terminal 34 to the tip 26.

The body 20 is sized to be relatively short compared to a typical test lead probe as is illustrated in FIG. 1. The axial length of the shaft 22 is short relative to the head 24. In this manner, the probe 12 easily remains in the socket of the terminal block 55 without creating undue stress on the terminal block due to remaining therein without the additional support of a hand.

Because each tip of a terminal block probe must be configured to be received the terminal socket of the terminal block, in accordance with an aspect of the present invention, reference is made to FIG. 4 wherein there is depicted a plurality of terminal block probes 70 constituting a terminal block probe kit. As indicated above this is because each style (configuration) of terminal block (usually by manufacturer) typically has its own style (configuration) of a terminal block socket and thus terminal block socket terminal. In order to provide hands free voltage testing of a terminal block, it is necessary to have various terminal block probes having different tips corresponding to the configuration of terminal socket for a particular terminal block.

FIG. 4 depicts three terminal block probes 12a, 12b and 12c representing any number of terminal block probes that may constitute a kit 70 of terminal block probes for use with a multi-meter for testing voltage at any one of a number of terminal blocks 55. It should be appreciated that the representation of tips of the present terminal block probes are exemplary and not necessarily illustrative of any particular or true-to-life terminal block socket. The kit 70 may or may not include a modular multi-meter test lead 40. The modular test lead 40 includes a probe plug 44 that is configured to be received by a socket 32a, 32b and 32c of respective probes 12a, 12b and 12c. The probe plug 44 is electrically connected to a wire/lead 42 that terminates in a test lead plug 46. The test lead plug 46 is adapted and/or configured to be received in an input of a multi-meter and/or a multi-meter test lead tool.

The terminal block probe 12a is like probe 12 in composition, configuration and function. As such, the terminal block probe 12a and has a body 20a defined by a generally short cylindrical shaft 22a terminating at one end in a head 24a and including a circumferential finger grip 28a. The body 20a may be formed of plastic but other materials may be used. The head 25a is generally frusto-conically shaped that axially extends from the grip 28a and terminates in an electrically conducting tip 26a. The grip 28a is generally saucer shaped and includes a flat 29a on one side or edge thereof. The flat 29a provides a handling surface for the terminal block probe 12a. The shaft 22a includes an opening or socket 32a in which is situated an electrical pad or terminal 34a. The socket 32a and electrical terminal 34a are configured to receive the modular end 44 of the modular test lead 40. In this regard, the terminal block probe 12a is a modular type probe. The terminal 34a is electrically connected to the electrically conducting tip 26a via a wire or the like 25a that extends through the body 20a from the terminal 34a to the tip 26a.

The body 20a is sized to be relatively short compared to a typical test lead probe such as is illustrated in FIG. 1 with regard to probe 10. The axial length of the shaft 22a is short relative to the head 24a. In this manner, the probe 12a easily remains in the socket of the terminal block 55 without creating undue stress on the terminal block due to remaining therein without the additional support of a hand.

The terminal block probe 12b is like probe 12 in composition, configuration and function. As such, the terminal block probe 12b and has a body 20b defined by a generally short cylindrical shaft 22b terminating at one end in a head 24b and including a circumferential finger grip 28b. The body 20b may be formed of plastic but other materials may be used. The head 25b is generally frusto-conically shaped that axially extends from the grip 28b and terminates in an electrically conducting tip 26b. The grip 28b is generally saucer shaped and includes a flat 29b on one side or edge thereof. The flat 29b provides a handling surface for the terminal block probe 12b. The shaft 22b includes an opening or socket 32b in which is situated an electrical pad or terminal 34b. The socket 32b and electrical terminal 34b are configured to receive the modular end 44 of the modular test lead 40. In this regard, the terminal block probe 12b is a modular type probe. The terminal 34b is electrically connected to the electrically conducting tip 26b via a wire or the like 25b that extends through the body 20b from the terminal 34b to the tip 26b.

The body 20b is sized to be relatively short compared to a typical test lead probe such as is illustrated in FIG. 1 with regard to probe 10. The axial length of the shaft 22b is short relative to the head 24a. In this manner, the probe 12b easily remains in the socket of the terminal block 55 without creating undue stress on the terminal block due to remaining therein without the additional support of a hand.

The terminal block probe 12c is like probe 12 in composition, configuration and function. As such, the terminal block probe 12c and has a body 20c defined by a generally short cylindrical shaft 22c terminating at one end in a head 24c and including a circumferential finger grip 28c. The body 20c may be formed of plastic but other materials may be used. The head 25c is generally frusto-conically shaped that axially extends from the grip 28c and terminates in an electrically conducting tip 26c. The grip 28c is generally saucer shaped and includes a flat 29c on one side or edge thereof. The flat 29c provides a handling surface for the terminal block probe 12c. The shaft 22c includes an opening or socket 32c in which is situated an electrical pad or terminal 34c. The socket 32c and electrical terminal 34c are configured to receive the modular end 44 of the modular test lead 40. In this regard, the terminal block probe 12c is a modular type probe. The terminal 34c is electrically connected to the electrically conducting tip 26c via a wire or the like 25c that extends through the body 20c from the terminal 34c to the tip 26c.

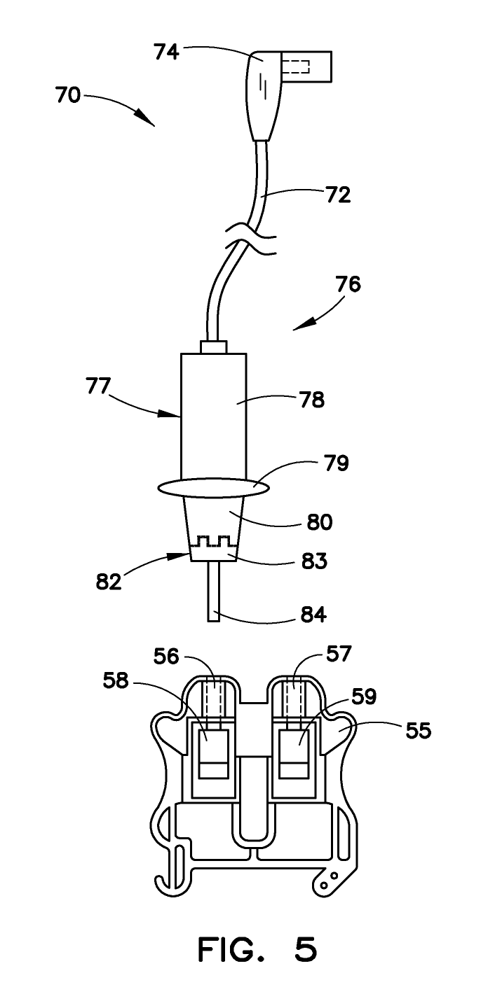

The body 20c is sized to be relatively short compared to a typical test lead probe such as is illustrated in FIG. 1 with regard to probe 10. The axial length of the shaft 22c is short relative to the head 24c. In this manner, the probe 12c easily remains in the socket of the terminal block 55 without creating undue stress on the terminal block due to remaining therein without the additional support of a hand. FIG. 5 depicts another embodiment of a terminal block probe, generally designated 76, that provides modularity by utilizing removable heads that have variously configured tips. The terminal block probe 76 may thus be considered part of the test lead 70. The test lead 70 includes test lead wire 72 terminating at one end in the terminal block probe 76 and at the other end in a multi-meter plug 74.

The terminal block probe 76 is similar in composition, configuration and function to the terminal block probe 12. As such, the terminal block probe 76 has a body 77 defined by a generally short cylindrical shaft 78 terminating at one end in a truncated head 80 and including a circumferential finger grip 79. The grip 79 is generally saucer shaped and may include a flat (not shown) on one side or edge thereof. The body 77 may be formed of plastic but other materials may be used. A tip assembly 83 having an electrically conducting tip 84 is removably received onto the head 80. The test lead 72 is electrically connected to the electrically conducting tip 84 via a wire or the like (not shown) that extends through the body 77 from the test lead 72 to the tip 83. The tip assembly 80 is one of various tip assemblies each one of which has a differently configured tip 84 to correspond with different configurations of terminal blocks. In this manner, only the head assembly of the probe 76 needs to be changed in order to accommodate different styles and/or configurations of terminal blocks, thereby creating another modular terminal block probe.

The terminal block probe 76 of FIG. 5 is shown ready to be inserted into a terminal block socket 56 wherein the tip 84 may contact the electrical terminal or contact 58 of the industrial terminal block 55. The socket 56 and thus the terminal 58 are the neutral, ground or negative terminal or contact. The industrial terminal block 55 may as shown, but may not, include a second terminal block socket 57 having an electrical terminal or contact 59 which are also a neutral, ground or negative terminal or contact. Alternatively, the socket 56 and thus the terminal or contact 58 may be a positive terminal or contact rather than a neutral, ground or negative terminal or contact. In this case, should the industrial terminal block 55 include a second socket 57 and electrical terminal or contact 59 such as shown, the second socket 57 and terminal or contact 59 would also be a positive terminal or contact.

The body 77 is sized to be relatively short compared to a typical test lead probe such as is illustrated in FIG. 1 with regard to probe 10. The axial length of the shaft 78 is short relative to the head 80. In this manner, the probe 76 easily remains in the socket of the terminal block 55 without creating undue stress on the terminal block due to remaining therein without the additional support of a hand.

Referring now to FIGS. 6-9, there is depicted various views of another embodiment of a terminal block test probe 12d fashioned in accordance with the present principles. The terminal block test probe 12d is a modular test probe similar to the three terminal block probes 12a, 12b and 12c of FIG. 4 and as such may constitute part of the kit 70 of terminal block probes for use with a multi-meter for electrical measurement/testing of various styles of terminal blocks. The modular test lead 40 includes a probe plug 44 that is configured to be received by a socket 32d of the probe 12d. The probe plug 44 is electrically connected to a wire/lead 42 that terminates in a test lead plug 46. The test lead plug 46 is adapted and/or configured to be received in an input of a multi-meter and/or a multi-meter test lead tool.

The terminal block probe 12d is like probes 12a-c in composition, configuration and function. As such, the terminal block probe 12d and has a body 20d defined by a generally short cylindrical shaft 22d terminating at one end in a head 24d and including a circumferential finger grip 28d. The body 20d may be formed of plastic but other materials may be used which are electrically non-conducting (dielectric) in like manner to the other probes shown and described herein. The head 24d is generally frusto-conically shaped that axially extends from the grip 28d and terminates in an electrically conducting tip 26d. Other configurations may be used. The grip 28d is generally saucer shaped and includes a flat 29d on one side or edge thereof. The flat 29d provides a handling surface for the terminal block probe 12d. Other configurations for the grip may be used. The shaft 22d includes an opening or socket 32d in which is situated an electrical pad or terminal 34d. The socket 32d and electrical terminal 34d are configured to receive the modular end 44 of the modular test lead 40. In this regard, the terminal block probe 12d is a modular type probe. The terminal 34d is electrically connected to the electrically conducting tip 26d via a wire or the like 25d that extends through the body 20d from the terminal 34d to the tip 26d.

The body 20d is sized to be relatively short compared to a typical test lead probe such as is illustrated in FIG. 1 with regard to probe 10. The axial length of the shaft 22d is short relative to the head 24d. In this manner, the probe 12d easily remains in the socket of various styles of terminal blocks without creating undue stress on the terminal block due to remaining therein without the additional support of a hand.

The electrically conductive tip 26d, as indicated above, is configured to provide temporary automatic electrical adjoining of the tip 26d (i.e. a self-adjoining tip) to a terminal of a terminal block (see, e.g., FIG. 10) in like manner to the tip 26c of the probe 12c. Additionally, however, the tip 26d is fashioned to have a bias member or element 64 that provides a spring resistance or resilience against a force or pressure applied thereto. This allows easy insertion of the tip 26d into a socket and/or opening of screw-clamp technology type terminal blocks, spring cage technology type terminal blocks, IDC technology type terminal block and/or any other type of terminal blocks, electrical contact with an appropriate terminal of the terminal block (i.e. establish an electrical contact point), and easy removal of the tip 26d. While the bias element and overall tip configuration may be different than that shown, in one form the bias element 64 is provided between first and second tip members or elements 63, 65 that may or may not be electrically conductive. While the first and second tip members 63, 65 are shown as identical, they may be configured in different manners as desired.

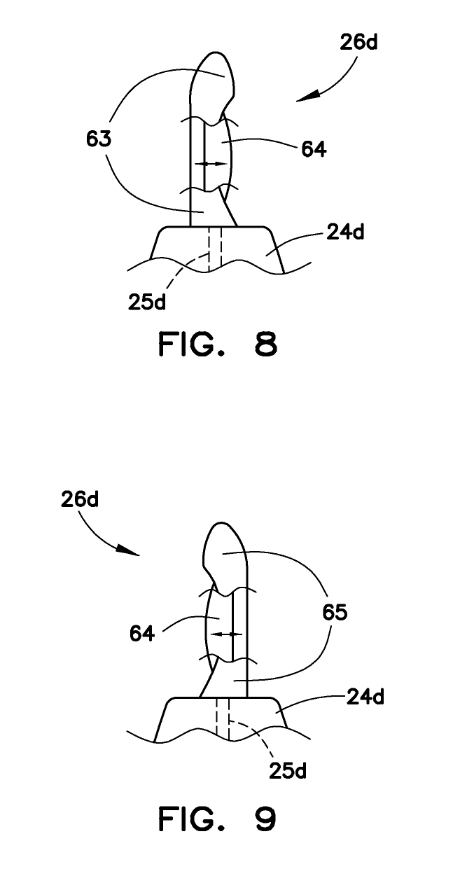

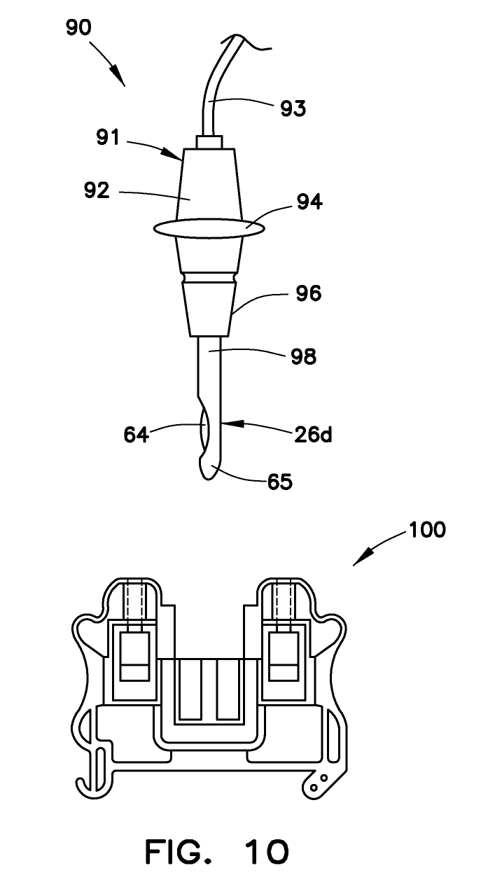

The bias element is formed of a resilient material and/or is mounted to and/or such in the head 24d of the probe 12d so as to flex, contract or deflect in the radial direction, as represented by the double-headed arrows of FIGS. 8 and 9, when a pressure or force is applied against thereto by a pressure element (e.g. a terminal of a terminal block). This provides a spring force, tension or resilience against the pressure element such that the bias element 64 makes physical contact, and thus electrical contact, with the particular pressure element. The bias element 64 is shown as curved in a convex manner so as to provide various contact surfaces along its length and at or in its upper and lower ends. The upper and lower ends create upper and lower pockets with the first and second tip elements 63, 65 because of their interacting curvatures. Thus, the bias element 64 is able to be compressed inwardly relative to the first and second tip elements 63, 65 to provide a self-adjoining tip 26d.

Referring now to FIG. 10, there is depicted another embodiment of a terminal block probe, generally designated 90, which is a non-modular terminal block probe having the self-adjoining tip 26d. The terminal block probe 90 may be considered part of a test lead 93. The test lead 93 includes test lead wire terminating at one end in the terminal block probe 90 and at the other end in a multi-meter plug, receptor, tool or other connector (not shown).

The terminal block probe 90 is similar in composition, configuration and function to the other terminal block probes shown and/or described herein. As such, the terminal block probe 90 has a body 91 defined by a generally short cylindrical shaft 92 terminating at one end in a truncated head 96 and including a circumferential finger grip 94. The grip 94 is generally saucer shaped and may include a flat (not shown) on one side or edge thereof. The body 91 may be formed of plastic but other materials may be used. The body may be made in various dimensions and/or configurations as desired. A tip assembly 98 having the electrically conducting self-adjoining tip 26d extends from the head 96. The tip assembly 98 may be longer or shorter as desired. The test lead 93 is electrically connected to the electrically conducting tip 26d via a wire or the like (not shown) that extends through the body 91 from the test lead 93 to the tip 26d.

The terminal block probe 90 of FIG. 10 is shown ready to be inserted into a terminal block socket of a terminal block 100, the terminal block 100 representing any one of a screw-clamp type terminal block, a spring-cage type terminal block, an IDC type terminal block, or another type of terminal block wherein the tip 26d may contact an electrical terminal or contact of the terminal block 100. The body 91 is sized to be relatively short compared to a typical test lead probe such as is illustrated in FIG. 1 with regard to probe 10 and/or is weighted accordingly to provide these properties. In the figure, the axial length of the probe shaft is short relative to the probe head. In this manner, the probe 90 easily remains in the socket or other opening of the terminal block 100 without creating undue stress on the terminal block due to remaining therein without the additional support of a hand.

While the invention has been illustrated and described in detail in the drawings and foregoing description, the same is to be considered as illustrative and not restrictive in character, it being understood that only preferred embodiments have been shown and described and that all changes and modifications that come within the spirit of the invention are desired to be protected.

What is claimed is:

1. A terminal block probe for use with a multi-meter, the terminal block probe comprising:
a body formed of a dielectric material and defining a first end and a second end;
an electrically conducting member extending from the first end of the body to the second end of the body; and
an electrically conducting tip extending outwardly from the second end of the body and electrically connected to the electrically conducting member, the electrically conducting tip dimensioned for reception in a terminal block opening of a terminal block and having a contact element that compresses upon application of a bias by a terminal within the terminal block opening of the terminal block to provide an electrical connection with the terminal.

2. The terminal block probe of claim 1, wherein the contact element compresses upon application of a bias by a terminal within the terminal block opening of the terminal block to provide releasable electrical connection with the terminal.

3. The terminal block probe of claim 1, wherein the dielectric material comprises a plastic.

4. The terminal block probe of claim 1, wherein the body is cylindrical with a tapered second end.

5. The terminal block probe of claim 4, wherein the cylindrical body includes a socket at its first end, the socket having an electrical pad electrically connected to the electrically conducting member and configured to releaseably receive a plug of a multi-meter test lead.

6. The terminal block probe of claim 1, wherein a multi-meter test lead is connected to the first end of the body and in electrical contact with the electrically conducting member.

7. The terminal block probe of claim 1, wherein the contact element of the electrically conducting tip is situated between first and second tip members.

8. The terminal block probe of claim 7, wherein the first and second tip members are electrically conductive.

9. The terminal block probe of claim 7, wherein the first and second tip members are electrically non-conductive.

10. A terminal block probe for use with a multi-meter, the terminal block probe comprising:
a cylindrical body formed of a dielectric and defining a first end and a second end;
an electrical conductor situated within the cylindrical body and extending from the first end to the second end of the body;
a grip extending radially from the cylindrical body proximate the second end; and
an electrically conductive, self-adjoining tip extending outwardly from the second end and in electrical connection with the electrical conductor.

11. The terminal block probe of claim 10, further comprising a multi-meter test lead extending from the first end of the body and in electrical connection with the electrical conductor.

12. The terminal block probe of claim 10, wherein the self-adjoining tip has a resilient member that creates releasable electrical contact with a terminal within an opening of a terminal block when the terminal block probe is received in the terminal block opening.

13. The terminal block probe of claim 12, wherein the resilient member is formed of a material that compresses upon application of a bias by the terminal within the terminal block opening of the terminal block to provide the releasable electrical contact with the terminal.

14. The terminal block probe of claim 10, wherein the self-adjoining tip includes a contact element situated between first and second tip members.

15. The terminal block probe of claim 14, wherein the first and second tip members are electrically conductive.

16. The terminal block probe of claim 14, wherein the first and second tip members are electrically non-conductive.

17. The terminal block probe of claim 10, wherein the dielectric material comprises a plastic.

18. The terminal block probe of claim 10, wherein the first end of the cylindrical body includes a socket housing an electrical pad electrically connected to the electrical conductor and configured to receive a plug of a multi-meter test lead.
